(19) United States
(12) Patent Application Publication
(10) Pub. No.: US 2025/0089186 A1
(43) Pub. Date: Mar. 13, 2025

(54) DISPLAY DEVICE

(71) Applicant: Samsung Display Co., LTD., Yongin-si (KR)

(72) Inventors: Jae Won JEONG, Yongin-si (KR); Jong Hyuck KIM, Yongin-si (KR); Ju Yeop SEONG, Yongin-si (KR); Hee Kwon LEE, Yongin-si (KR); Jae Soo JANG, Yongin-si (KR)

(21) Appl. No.: 18/656,434

(22) Filed: May 6, 2024

(30) Foreign Application Priority Data
Sep. 8, 2023 (KR) 10-2023-0119332

(51) Int. Cl. H05K 5/02

(52) U.S. Cl. CPC H05K 5/0217

(57) ABSTRACT

The present disclosure relates to a display device, and more particularly, to a display device that can prevent distortion of driving members. A display device includes: a display panel; a first main guide rail and a second main guide rail disposed on a first side and a second side of the display panel, respectively; and a first driving member disposed between the first main guide rail and the second main guide rail. The first driving member is selectively coupled to the first main guide rail from among the first main guide rail and the second main guide rail and is not coupled to the second main guide rail.

This application claims priority to Korean Patent Application No. 10-2023-0119332 filed on Sep. 8, 2023, and all the benefits accruing therefrom under 35 U.S.C. § 119, the content of which in its entirety is herein incorporated by reference.

### BACKGROUND

### 1. Field of the Disclosure

The present disclosure relates to a display device, and more particularly, to a display device that can prevent distortion of driving members.

### 2. Description of the Related Art

Display devices become more and more important as multimedia technology evolves. Accordingly, a variety of types of display devices such as, for example, organic light-emitting display (OLED) devices and liquid-crystal display (LCD) devices are currently used.

Recently, with the evolution of display technology, research and development of display devices having a flexible display is ongoing. The display screen of some flexible displays can be extended or reduced by folding, bending, or sliding the display screen, which may thereby contribute greatly to reductions in volume or design changes of the display device.

### SUMMARY

Aspects of the present disclosure provide a display device that can prevent distortion of driving members.

According to an embodiment of the disclosure, a display device includes: a display panel; a first main guide rail and a second main guide rail disposed on a first side and a second side of the display panel, respectively; and a first driving member disposed between the first main guide rail and the second main guide rail, wherein the first driving member is selectively coupled to the first main guide rail from among the first main guide rail and the second main guide rail and is not coupled to the second main guide rail.

In an embodiment, the first driving member may include: rod; and a main coupler disposed at an end of the rod and coupled to the first main guide rail.

In an embodiment, the main coupler of the first driving member may include: a first protrusion protruding from the rod and facing an outer surface of the first main guide rail; and a second protrusion disposed on an opposite side of the first protrusion and facing an inner surface of the first main guide rail.

In an embodiment, the main coupler of the first driving member further may include a connector connecting the first protrusion with the second protrusion.

In an embodiment, the first driving member further may include a third protrusion protruding from an opposite end of the rod.

In an embodiment, the third protrusion faces an outer surface of the second main guide rail.

In an embodiment, the first driving member further may include an auxiliary coupler disposed on the rod.

In an embodiment, the display device may further include an auxiliary guide rail to which the auxiliary coupler is coupled.

In an embodiment, the auxiliary guide rail may include a first rail and a second rail that are spaced apart from and face each other, and define a guide hole into which the auxiliary coupler is coupled.

In an embodiment, the auxiliary coupler may include: a supporter protruding from an upper surface of the rod; and a locking means disposed on the supporter and inserted into the guide hole.

In an embodiment, the auxiliary coupler is disposed at a center of the rod.

In an embodiment, the auxiliary coupler may include a first auxiliary coupler disposed adjacent to an end of the rod; and a second auxiliary coupler disposed adjacent to an opposite end of the rod.

In an embodiment, the display device may further include: a first auxiliary guide rail to which the first auxiliary coupler is coupled; and a second auxiliary guide rail to which the second auxiliary coupler is coupled.

In an embodiment, the first auxiliary guide rail and the second auxiliary guide rail are disposed between the first main guide rail and the second main guide rail.

In an embodiment, the first auxiliary guide rail is disposed adjacent to the first main guide rail, and the second auxiliary guide rail is disposed adjacent to the second main guide rail.

In an embodiment, the display device may further include: a second driving member disposed adjacent to the first driving member between the first main guide rail and the second main guide rail, wherein the second driving member is selectively coupled to the second main guide rail from among the first main guide rail and the second main guide rail and is not coupled to the first main guide rail.

In an embodiment, the second driving member may include: a rod; and a main coupler disposed at an end of the rod and coupled to the second main guide rail.

In an embodiment, the main coupler of the second driving member may include: a first protrusion protruding from the rod and facing an outer surface of the second main guide rail; and a second protrusion disposed on an opposite side of the first protrusion and facing an inner surface of the second main guide rail.

In an embodiment, the main coupler of the first driving member further may include a connector connecting the first protrusion with the second protrusion.

According to an embodiment of the disclosure, a display device includes: a display panel; a first main guide rail and a second main guide rail disposed on a first side and a second side of the display panel, respectively; an auxiliary guide rail disposed between the first main guide rail and the second main guide rail; and a driving member disposed between the first main guide rail and the second main guide rail and coupled to the auxiliary guide rail.

In an embodiment, an end of the driving member may face an outer surface of the first main guide rail, and an opposite end of the driving member may face an outer surface of the second main guide rail.

In an embodiment, the driving member may include an auxiliary coupler coupled to the auxiliary guide rail.

According to an embodiment of the disclosure, a display device includes: a display panel; a first main guide rail and a second main guide rail disposed on a first side and a second side of the display panel, respectively; and a driving member disposed between the first main guide rail and the second main guide rail, wherein the driving member includes a first sub-driving member and a second sub-driving member that are separated from each other and coupled to the first main guide rail and the second main guide rail, respectively.

In an embodiment, the first sub-driving member may include a first main coupler coupled to the first main guide rail, and the second sub-driving member may include a second main coupler coupled to the second main guide rail.

In an embodiment, the first sub-driving member may include a first auxiliary coupler, and the second sub-driving member may include a second auxiliary coupler.

In an embodiment, the display device may further include: a first auxiliary guide rail to which the first auxiliary coupler is coupled; and a second auxiliary guide rail to which the second auxiliary coupler is coupled.

A display device of the present disclosure can provide the following effects:
First, distortion of driving members and a display panel can be prevented;
Second, the fabrication cost of the display device can be reduced;
Third, the weight of the driving members can be reduced;
Fourth, the friction between the driving members and main guide rails can be reduced; and
Fifth, the driving force for driving the driving members can be distributed.

The effects of the present disclosure are not limited to the above-described effects, and other effects which are not described herein will become apparent to those skilled in the art from the following description.

### BRIEF DESCRIPTION

The above and other aspects and features of the present disclosure will become more apparent by describing in detail example embodiments thereof with reference to the attached drawings, in which:

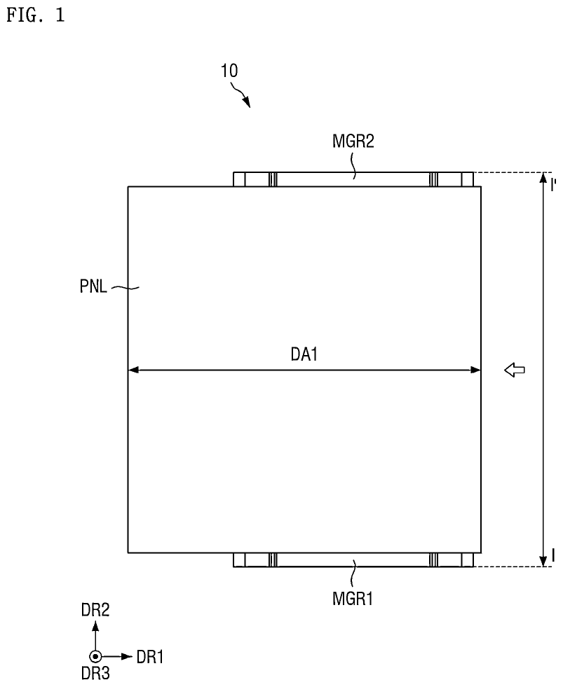

FIG. 1 is a plan view of a display device according to an embodiment of the present disclosure.

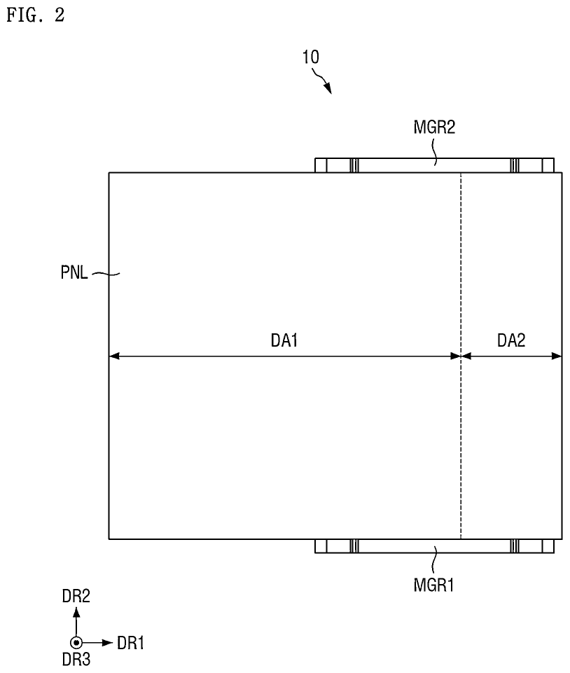

FIG. 2 is a view for illustrating the expanded shape of the display panel of FIG. 1.

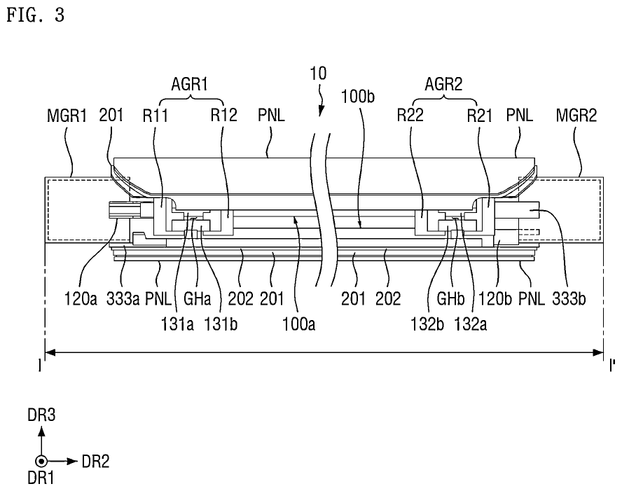

FIG. 3 is a cross-sectional view illustrating the shape of the display device taken along line I-I′ of FIG. 1 when viewed in the direction indicated by an arrow.

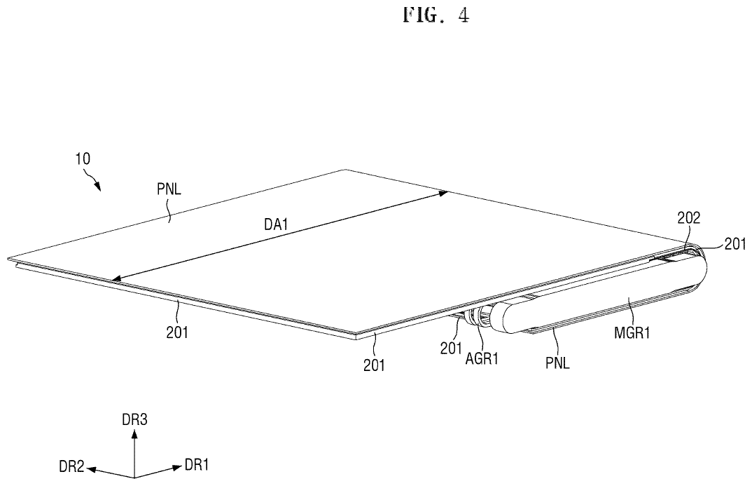

FIG. 4 is a perspective view of the display device of FIG. 1.

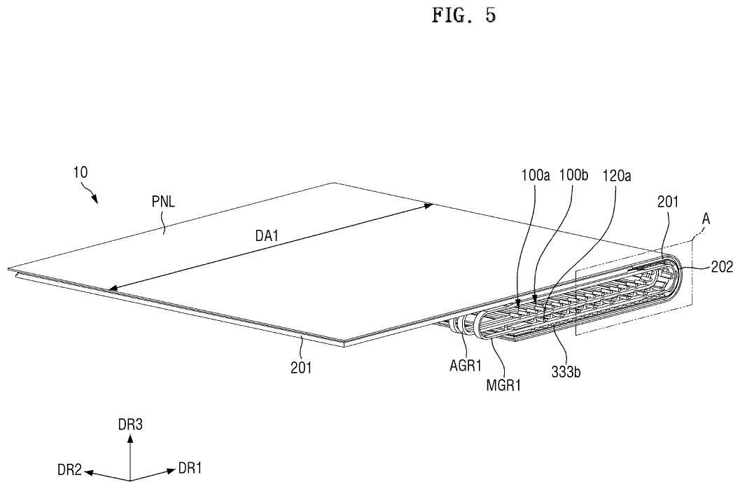

FIG. 5 is a cut-away view of a first main guide rail in the display device of FIG. 4.

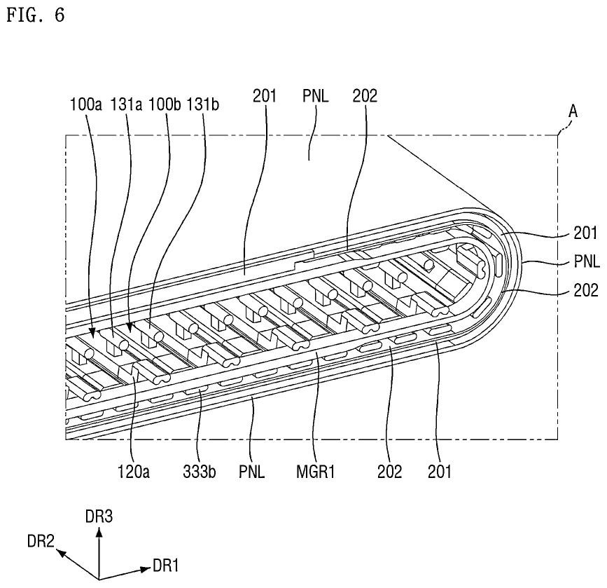

FIG. 6 is a first enlarged view of area A of FIG. 5.

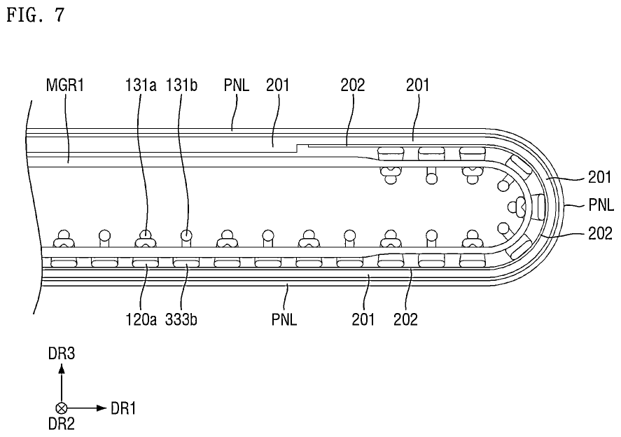

FIG. 7 is a side view of FIG. 6.

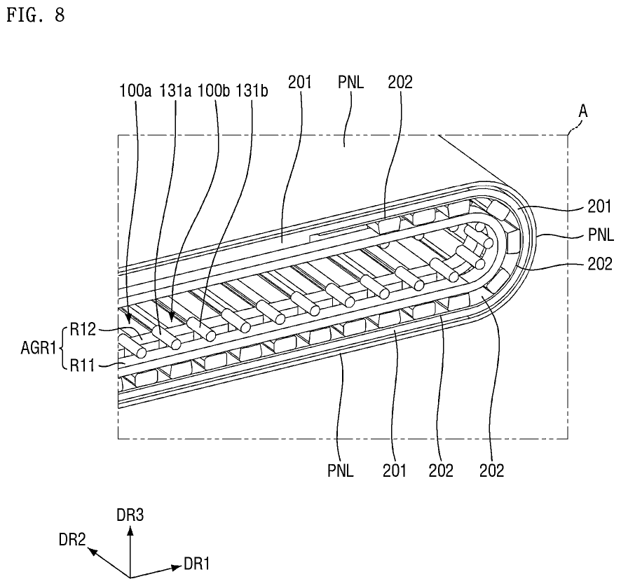

FIG. 8 is a second enlarged view of area A of FIG. 5.

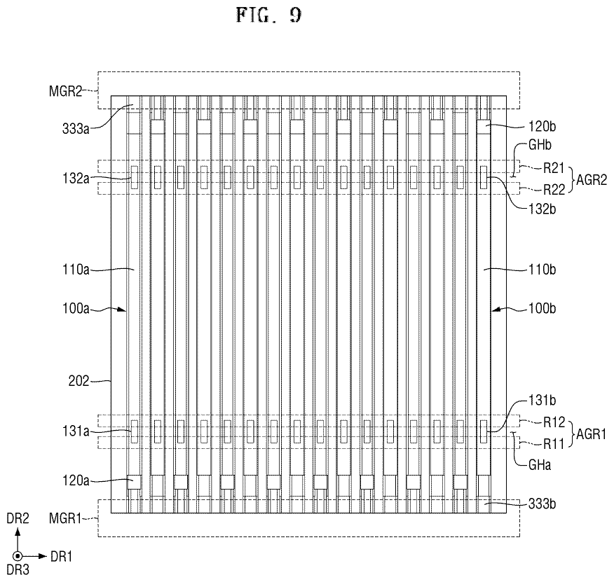

FIG. 9 is a plan view of a plurality of driving members and a second support plate according to the embodiment of FIG. 5.

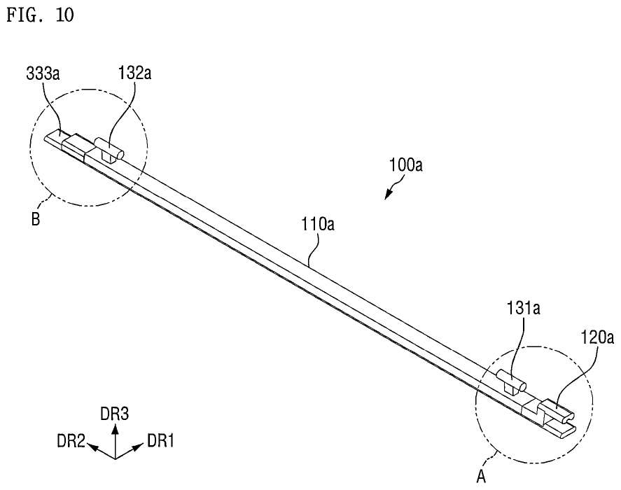

FIG. 10 is a perspective view of the first driving member of FIG. 9.

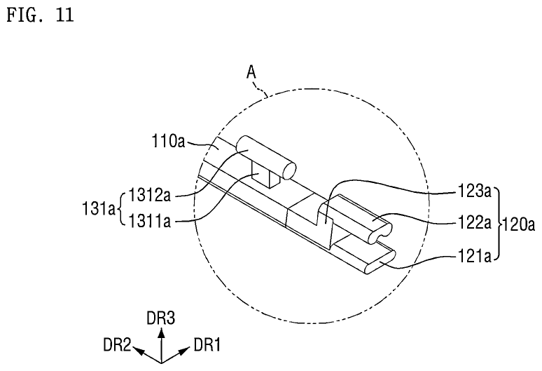

FIG. 11 is an enlarged view of part A of FIG. 10.

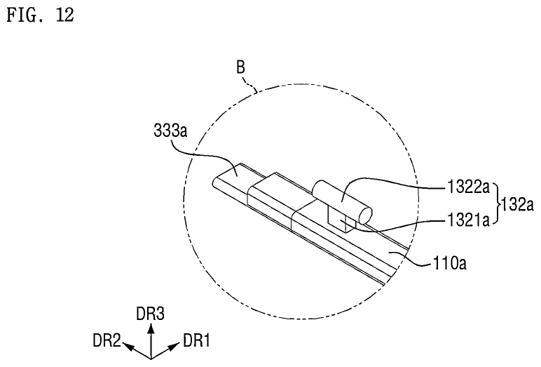

FIG. 12 is an enlarged view of area B of FIG. 10.

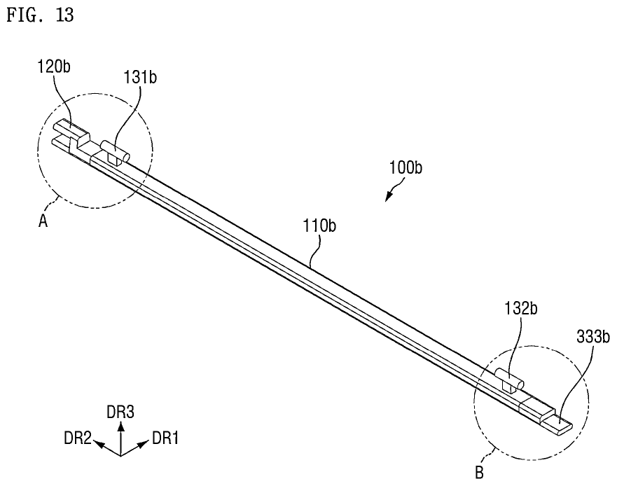

FIG. 13 is a perspective view of the second driving member of FIG. 9.

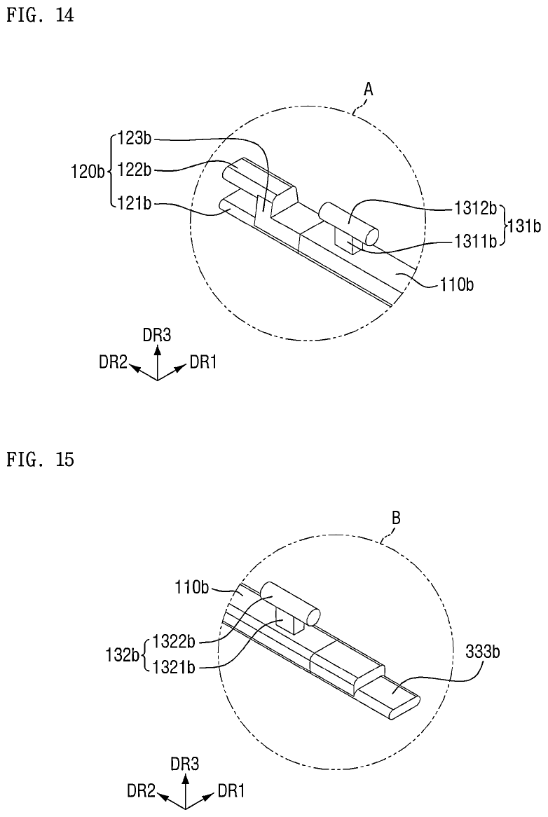

FIG. 14 is an enlarged view of part A of FIG. 13.

FIG. 15 is an enlarged view of part B of FIG. 13.

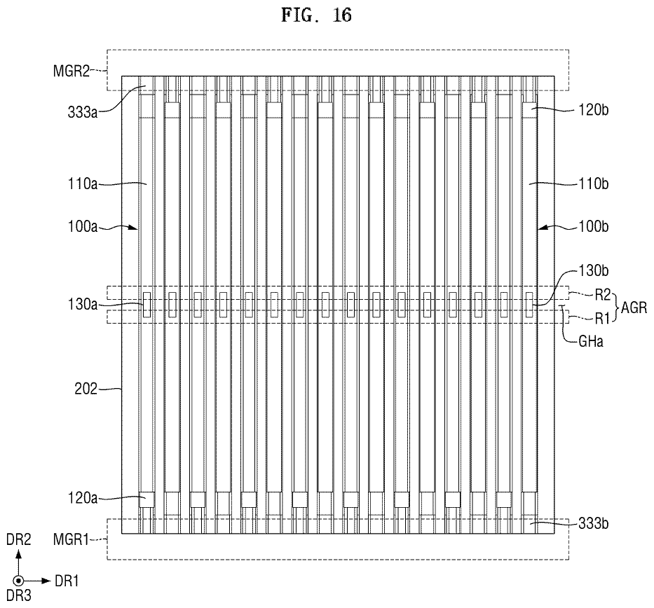

FIG. 16 is a plan view of a plurality of driving members and a second support plate according to an embodiment.

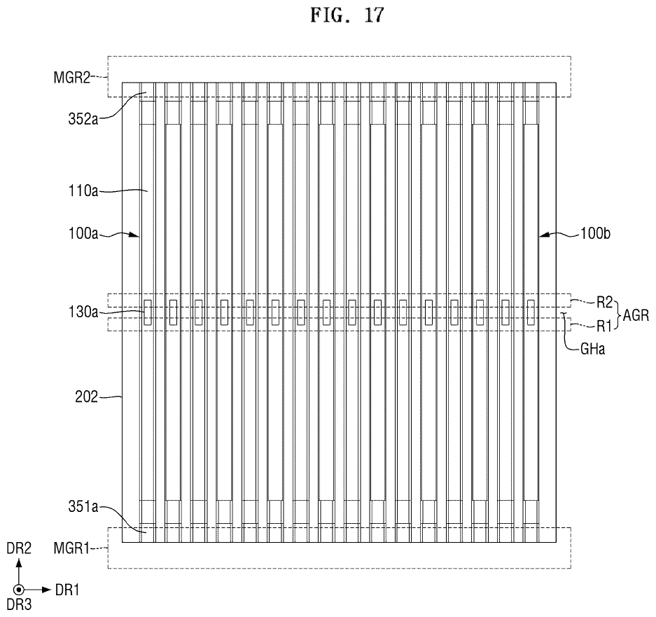

FIG. 17 is a plan view of a plurality of driving members and a second support plate according to an embodiment.

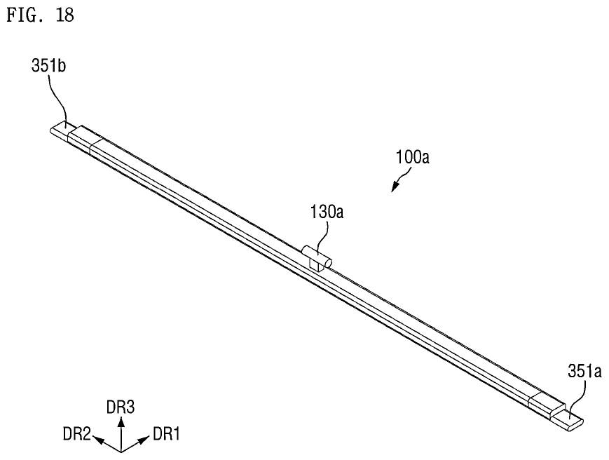

FIG. 18 is a perspective view of the first driving member of FIG. 17.

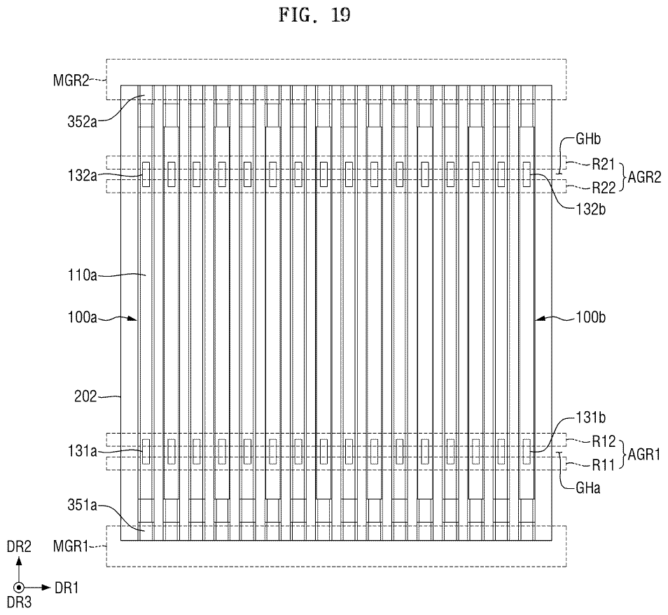

FIG. 19 is a plan view of a plurality of driving members and a second support plate according to an embodiment.

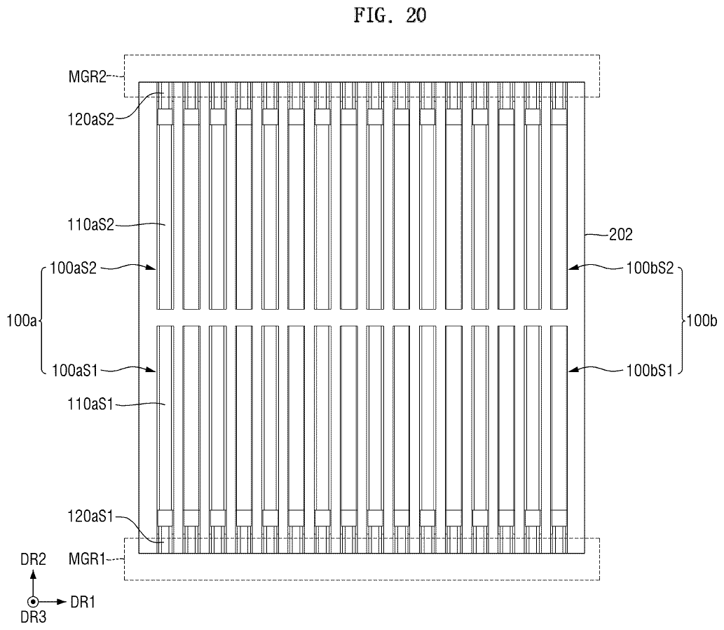

FIG. 20 is a plan view of a plurality of driving members and a second support plate according to an embodiment.

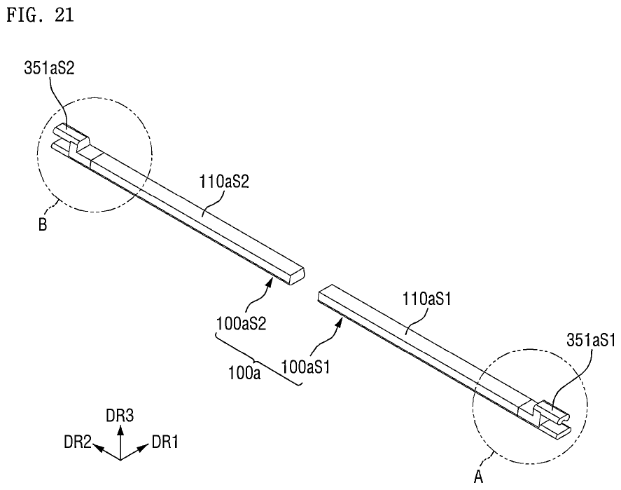

FIG. 21 is a perspective view of the first driving member of FIG. 20.

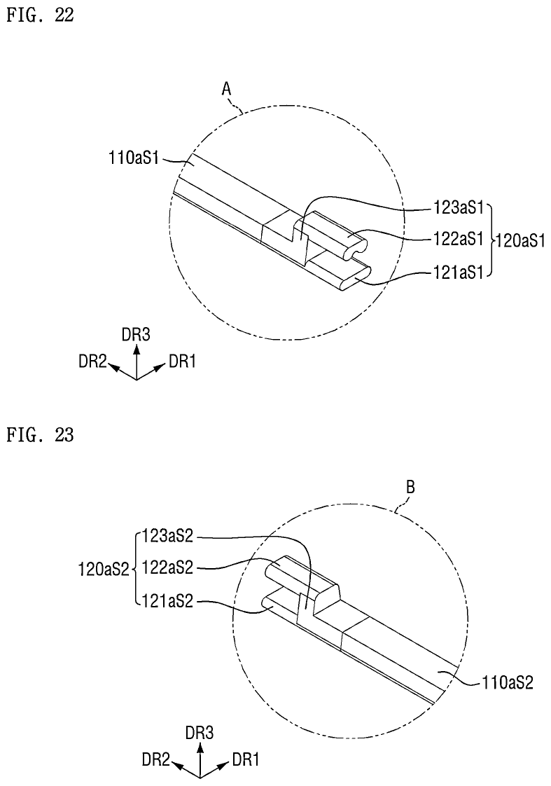

FIG. 22 is an enlarged view of part A of FIG. 21.

FIG. 23 is an enlarged view of area B of FIG. 21.

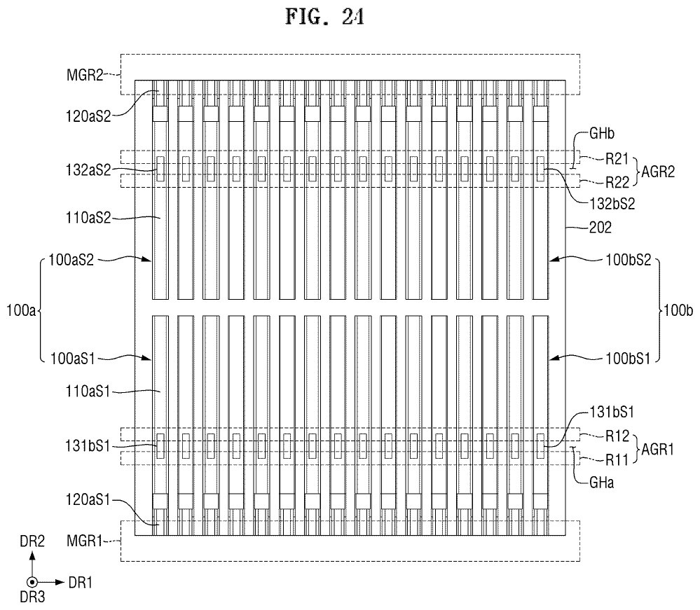

FIG. 24 is a plan view of a plurality of driving members and a second support plate according to an embodiment.

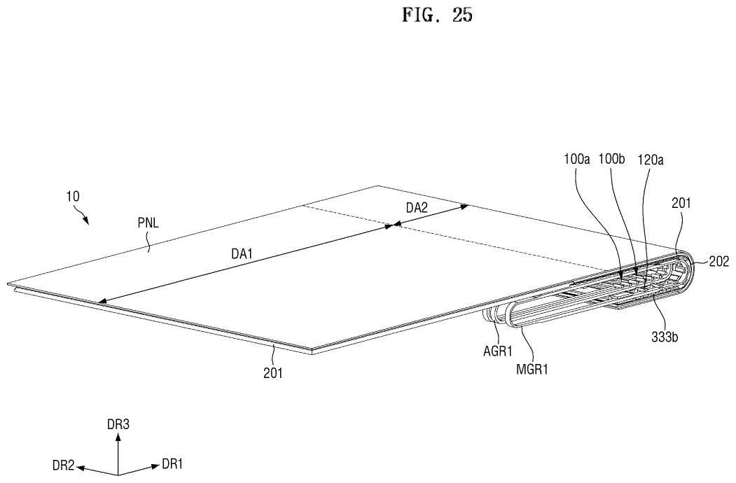

FIG. 25 is a view for illustrating the expanded shape of the display panel of FIG. 5.

### DETAILED DESCRIPTION

Hereinafter, example embodiments of the present disclosure will be described with reference to the accompanying drawings.

FIG. 1 is a plan view of a display device 10 according to an embodiment of the present disclosure. FIG. 2 is a view for illustrating the expanded shape of the display panel PNL of FIG. 1. FIG. 3 is a cross-sectional view illustrating the shape of the display device 10 taken along line I-I′ of FIG. 1 when viewed in the direction indicated by an arrow.

The display device 10 according to the embodiment may be a sliding display device 10 or a slideable display device 10 that can slide. In some embodiments, the display device 10 may be, but is not limited to, a single-direction slideable display device 10 (also referred to herein as a single-slideable display device 10) that can slide in one direction (e.g., a first direction DR1 and a direction opposite to the first direction DR1). For example, the display device 10 according to some embodiments may be a multi-direction slideable display device 10 (also referred to herein as a multi-slidable display device 10) capable of sliding in multiple directions (e.g., the first direction DR1 and the direction opposite to the first direction DR1, and a second direction DR2 and a direction opposite to the second direction DR2). The following description will focus on a single-slidable display device 10, but aspects of the present disclosure are not limited thereto.

The display device 10 according to the embodiments described herein may include a display panel PNL, a first support plate 201, a second support plate 202, a first main guide rail MGR1, a second main guide rail MGR2, a first auxiliary guide rail AGR1, and a second auxiliary guide rail AGR2, as illustrated in FIGS. 1 to 3.

The display panel PNL may display images thereon. Embodiments of the present disclosure support employing any suitable type of display panel as the display panel PNL, such as, for example, an organic light-emitting display panel including an organic light-emitting layer, a micro light-emitting diode display panel using micro LEDs, a quantum-dot light-emitting display panel using quantum-dot light-emitting diodes including quantum-dot light-emitting layer, and an inorganic light-emitting display panel using inorganic light-emitting elements including an inorganic semiconductor.

The display panel PNL may be a flexible panel. The display panel PNL may have flexibility such that the display panel PNL can be partially rolled, bent, or curved along a first main guide rail MGR1 and a second main guide rail MGR2. The display panel PNL may slide in the first direction DR1 and the direction opposite to the first direction DR1 (hereinafter referred to as a first opposite direction).

The outer surface (e.g., the surface illustrated in FIG. 1) of the display panel PNL may be a surface on which images are displayed. In some embodiments, the inner surface of the display panel PNL may face the first support plate 201. The inner surface of the display panel PNL may be disposed opposite to the outer surface of the display panel PNL. The inner and outer surfaces of the first support plate 201, which will be described later, may be disposed on opposite sides of each other, and the outer and inner surfaces of the second support plate 202 may be disposed on opposite sides of each other.

The area of the display area of the display panel PNL may vary based on whether the display device 10 is slid open or is closed. For example, when the display device 10 is closed or is not slid open (hereinafter referred to as a first state or closed state), the display panel PNL may have a first display area DA_1 of a first area. In an example in which the display device 10 is slid open (hereinafter referred to as a second state or open state), the display area may further include an expanded second display area DA_2 in addition to the first display area DA_1. In some aspects, the area of the display area in the first state and the area of the display area in the second state may vary based on the degree of sliding of the display device 10. For example, as the degree of sliding of the display device 10 increases, the area of the display area in the first state or the area of the display area in the second state may increase. Expressed another way, the area of the display area of the display panel PNL may vary based on the state of the display device 10. In the open state, the area of the display area of the display panel PNL may be based on the degree of the open state (e.g., the amount in which the display device 10 is slid open).

The display panel PNL may be disposed on the outer surface of the first support plate 201. The display panel PNL may be attached to the outer surface of the first support plate 201. For example, the inner surface of the display panel PNL may be attached to the outer surface of the first support plate 201. The display panel PNL may be fixed to the first support plate 201. The first support plate 201 may be formed of a flexible material that can be bent.

The second support plate 202 may be disposed on the inner surface of the first support plate 201. The second support plate 202 may be attached to the inner surface of the first support plate 201. For example, the outer surface of the second support plate 202 may be attached to the inner surface of the first support plate 201. The second support plate 202 may be fixed to the first support plate 201. The second support plate 202 may be formed of a flexible material that can be bent.

A plurality of driving members 100a and 100b may be disposed on the inner surface of the second support plate 202. For example, the plurality of driving members 100a and 100b may be disposed on the second support plate 202 such that the plurality of driving members 100a and 100b are equally spaced apart from each other in the first direction DR1. The plurality of driving members 100a and 100b may be arranged parallel to each other. A plurality of driving members 100a and 100b may be attached to the inner surface of the first support plate 201. The plurality of driving members 100a and 100b may be fixed to the first support plate 201.

The first main guide rail MGR1 may be disposed on a side of the display panel PNL.

The second main guide rail MGR2 may be disposed on the opposite side of the display panel PNL. In other words, the second main guide rail MGR2 may be disposed opposite (e.g., on the opposite side of) the first main guide rail MGR1. For example, the first main guide rail MGR1 and the second main guide rail MGR2 may be disposed on opposite sides of each other in the second direction DR2. In some aspects, the first main guide rail MGR1 and the second main guide rail MGR2 may face away from each other in the second direction DR2. Alternatively, the first main guide rail MGR1 and the second main guide rail MGR2 may face each other in the second direction DR2.

As illustrated in FIG. 3, the first auxiliary guide rail AGR1 and the second auxiliary guide rail AGR2 may be disposed between the first main guide rail MGR1 and the second main guide rail MGR2. The first auxiliary guide rail AGR1 may be disposed opposite (e.g., on the opposite side of) the second auxiliary guide rail AGR2. The first auxiliary guide rail AGR1 may be disposed adjacent to the first main guide rail MGR1, and the second auxiliary guide rail AGR2 may be disposed adjacent to the second main guide rail MGR2.

As illustrated in FIG. 3, the plurality of driving members 100a and 100b may be disposed between the first main guide rail MGR1 and the second main guide rail MGR2.

The driving members 100a and 100b may be movably coupled to one of the first main guide rail MGR1 and the second main guide rail MGR2. In some aspects, the driving members 100a and 100b may be movably coupled to the first auxiliary guide rail AGR1 and the second auxiliary guide rail AGR2.

FIG. 4 is a perspective view of the display device 10 of FIG. 1. FIG. 5 is a cut-away view of the first main guide rail MGR1 in the display device 10 of FIG. 4. FIG. 6 is a first enlarged view of area A of FIG. 5. FIG. 7 is a side view of area A illustrated at FIG. 6. FIG. 8 is a second enlarged view of area A of FIG. 5. FIG. 9 is a plan view of the driving members 100a and 100b and the second support plate 202 according to the embodiment of FIG. 5.

In the first enlarged view illustrated in FIG. 6, the first auxiliary guide rail AGR1 is not illustrated among the elements of area A of FIG. 5 so as not to obstruct from the descriptions herein. In the second enlarged view illustrated in FIG. 8, the first main guide rail MGR1 and the coupler are not illustrated among the elements of area A of FIG. 5 so as not to obstruct from the descriptions herein.

As illustrated in FIG. 4, the first main guide rail MGR1 may be disposed on a side of the display panel PNL. The first main guide rail MGR1 may have an elliptical shape. Although not illustrated in FIG. 4, the second main guide rail MGR2 may have the same configuration as the first main guide rail MGR1. For example, the second main guide rail MGR2 may have an elliptical shape which is identical or substantially identical to the elliptical shape of the first main guide rail MGR1.

As illustrated in FIGS. 3, 5, 6, 7 and 9, the plurality of driving members 100a and 100b may be coupled with one of the first main guide rail MGR1 and the second main guide rail MGR2. In other words, the plurality of driving members 100a and 100b may be movably coupled to one of the first main guide rail MGR1 and the second main guide rail MGR2. For example, the plurality of driving members 100a and 100b may move in the first main guide rail MGR1 and the second main guide rail MGR2.

As illustrated in FIGS. 3 and 9, each of the driving members 100a and 100b may have a bar shape extended in the second direction DR2.

Each of the driving members 100a and 100b may be selectively coupled to one of the first main guide rail MGR1 and the second main guide rail MGR2, without being coupled to the other of the first main guide rail MGR1 and the second main guide rail MGR2. For example, each of the driving members 100a and 100b may be selectively coupled to one of (e.g., only one of) the first main guide rail MGR1 and the second main guide rail MGR2. In an example, the first driving member 100a may be coupled to the first main guide rail MGR1, and the second driving member 100b may be coupled to the second main guide rail MGR2, where the driving member disposed in the odd-numbered column (or even-numbered column) is defined as the first driving member 100a with respect to the first direction DR1, and the driving member disposed in the even-numbered column (or odd-numbered column) is defined as the second driving member 100b with respect to the first direction DR1. The first driving member 100a and the second driving member 100b may be arranged alternately. In other words, a plurality of first driving members 100a and a plurality of second driving members 100b may be arranged alternately.

In some aspects, as illustrated in FIGS. 3, 5, 6, 7 and 9, the plurality of driving members 100a and 100b may be movably connected to the first auxiliary guide rail AGR1 and the second auxiliary guide rail AGR2. For example, each of the plurality of first driving members 100a may be movably coupled to the first auxiliary guide rail AGR1 and the second auxiliary guide rail AGR2, and each of the plurality of second driving members 100b may be movably coupled to the first auxiliary guide rail AGR1 and the second auxiliary guide rail AGR2.

As illustrated in FIGS. 3, 5, 8 and 9, the first auxiliary guide rail AGR1 may include a first rail R11 and a second rail R12 that face each other and are spaced apart from each other. A guide hole GHa may be located between the first rail R11 and the second rail R12. For example, the first rail R11 and the second rail R12 may define the guide hole GHa.

As illustrated in FIGS. 3, 5, 8 and 9, the second auxiliary guide rail AGR2 may include a first rail R21 and a second rail R22 that face each other and are spaced apart from each other. A guide hole GHb may be located between the first rail R21 and the second rail R22. For example, the first rail R21 and the second rail R22 may define the guide hole GHb. The configuration of the second auxiliary guide rail AGR2 may be identical to or substantially the same as the configuration of the first auxiliary guide rail AGR1 described herein.

Each of the driving members 100a and 100b may be coupled to the first auxiliary guide rail AGR1 and the second auxiliary guide rail AGR2. For example, each of the driving members 100a and 100b may be coupled into the guide hole GHa of the first auxiliary guide rail AGR1 and the guide hole GHb of the second auxiliary guide rail AGR2.

As described herein, each of the driving members 100a and 100b is coupled to the first main guide rail MGR1 or the second main guide rail MGR2 and may also be coupled to the first auxiliary guide rail AGR1 and the second auxiliary guide rail AGR2. For example, the first driving member 100a may be coupled to the first main guide rail MGR1, the first auxiliary guide rail AGR1, and the second auxiliary guide rail AGR2. In the example, the second driving member 100b may be coupled to the second main guide rail MGR2, the first auxiliary guide rail AGR1, and the second auxiliary guide rail AGR2.

As illustrated in FIG. 9, a first driving member 100a may include a rod 110a, a main coupler 120a, a first auxiliary coupler 131a, and a second auxiliary coupler 132a.

The rod 110a of the first driving member 100a may have a bar shape extended in the second direction DR2.

The main coupler 120a of the first driving member 100a may be disposed at an end of the rod 110a. The main coupler 120a of the first driving member 100a may be coupled to the first main guide rail MGR1.

The first auxiliary coupler 131a of the first driving member 100a may be disposed on the rod 110a such that the first auxiliary coupler 131a is adjacent to an end (or the main coupler 120a) of the first driving member 100a. For example, the first auxiliary coupler 131a of the first driving member 100a may be disposed on the rod 110a between an end (or the main coupler 120a) of the rod 110a and the center of the rod 110a. The end and the other end of the rod 110a of the first driving member 100a may be disposed on opposite sides of each other. For example, an end of the rod 110a of the first driving member 100a may be disposed adjacent to the first main guide rail MGR1, and the other end of the rod 110a of the second driving member 100b may be disposed adjacent to the second main guide rail MGR2.

The second auxiliary coupler 132a of the first driving member 100a may be disposed on the rod 110a such that the second auxiliary coupler 132a is adjacent to the other end of the first driving member 100a. For example, the second auxiliary coupler 132a of the first driving member 100a may be disposed on the rod 110a between the other end of the rod 110a and the center of the rod 110a.

The rod 110a, the main coupler 120a, the first auxiliary coupler 131a, and the second auxiliary coupler 132a of the first driving member 100a may be formed as one body.

The second driving member 100b may include a rod 110b, a main coupler 120b, a first auxiliary coupler 131b, and a second auxiliary coupler 132b, as illustrated in FIG. 9.

The rod 110b of the second driving member 100b may have a bar shape extended in the second direction DR2.

The main coupler 120b of the second driving member 100b may be disposed at the other end of the rod 110b. The main coupler 120b of the second driving member 100b may be coupled to the second main guide rail MGR2.

The first auxiliary coupler 131b of the second driving member 100b may be disposed on the rod 110b such that the first auxiliary coupler 131b is adjacent to an end of the second driving member 100b. For example, the first auxiliary coupler 131b of the second driving member 100b may be disposed on the rod 110b between the end of the rod 110b and the center of the rod 110b. The end and the other end of the rod 110b of the second driving member 100b may be disposed on opposite sides of each other. For example, the end of the rod 110a of the second driving member 100b may be disposed adjacent to the first main guide rail MGR1, and the other end of the rod 110a of the second driving member 100b may be disposed adjacent to the second main guide rail MGR2.

The second auxiliary coupler 132b of the second driving member 100b may be disposed on the rod 110 such that the second auxiliary coupler 132b is adjacent to the other end (or the main coupler 120b) of the second driving member 100b. For example, the second auxiliary coupler 132b of the second driving member 100b may be disposed on the rod 110b between the other end (or the main coupler 120b) of the rod 110b and the center of the rod 110b.

The rod 110b, the main coupler 120b, the first auxiliary coupler 131b, and the second auxiliary coupler 132b of the second driving member 100b may be formed as one body.

According to the embodiments described herein, the first main guide rail MGR1 may include a straight portion and a curved portion as illustrated in FIG. 7, and the thickness of the straight portion may be different from the thickness of the curved portion. For example, the thickness of the curved portion may be greater than the thickness of the straight portion. Alternatively, the thickness of the straight portion may be equal to the thickness of the curved portion.

In some embodiments, characteristics of the second main guide rail MGR2 may be identical or substantially identical to characteristics of the first main guide rail MGR1. For example, the second main guide rail MGR2 may include a straight portion and a curved portion, and the thickness of the straight portion may be different from the thickness of the curved portion. For example, the thickness of the curved portion may be greater than the thickness of the straight portion. Alternatively, the thickness of the straight portion may be equal to the thickness of the curved portion.

FIG. 10 is a perspective view of the first driving member 100a of FIG. 9. FIG. 11 is an enlarged view of portion A of FIG. 10. FIG. 12 is an enlarged view of portion B of FIG. 10.

As illustrated in FIG. 10, a first driving member 100a may include a rod 110a, a main coupler 120a, a first auxiliary coupler 131a, and a second auxiliary coupler 132a.

As described herein, the main coupler 120a of the first driving member 100a may be disposed at an end of the rod 110a. The first main coupler 120a of the first driving member 100a may include a first protrusion 121a, a second protrusion 122a and a connector 123a, as illustrated in FIG. 11. The main coupler 120a may have, for example, a rectangular cross-section or a circular cross-section.

The first protrusion 121a of the first driving member 100a may protrude from the rod 110a. For example, the first protrusion 121a may protrude in a direction opposite to the second direction DR2 (hereinafter referred to as the second opposite direction).

The second protrusion 122a of the first driving member 100a may face the first protrusion 121a. The second protrusion 122a may protrude in the second opposite direction. The second protrusion 122a may be parallel to the first protrusion 121a. The first main guide rail MGR1 may be disposed between the first protrusion 121a and the second protrusion 122a of the first driving member 100a. In other words, the first driving member 100a may be coupled to the first main guide rail MGR1 by the first protrusion 121a and the second protrusion 122a of the main coupler 120a. In an example in which the first driving member 100a is coupled to the first main guide rail MGR1, the first protrusion 121a of the first driving member 100a may face the outer surface (or outer peripheral surface) of the first main guide rail MGR1, and the second protrusion 122a of the first driving member 100a may face the inner surface (or inner peripheral surface) of the first main guide rail MGR1.

The connector 123a of the first driving member 100a may connect the first protrusion 121a with the second protrusion 122a. The connector 123a may protrude from the first protrusion 121a in the third direction DR3. The connector 123a may be disposed between the first protrusion 121a and the second protrusion 122a. One side of the connector 123a may be connected to the first protrusion 121a, and the opposite side of the connector 123a may be connected to the second protrusion 122a. The first protrusion 121a, the second protrusion 122a, and the connector 123a may be formed as one body.

The main coupler 120a including the first protrusion 121a, the second protrusion 122a, and the connector 123a may have, for example, a C-shape or a U-shape.

The first auxiliary coupler 131a of the first driving member 100a may include a supporter 1311a and a locking means 1312a, as illustrated in FIG. 11.

The supporter 1311a of the first auxiliary coupler 131a of the first driving member 100a may protrude from the upper surface of the rod 110a in the third direction DR3. The upper surface of the rod 110a may be opposite to the lower surface of the rod 110a, and the lower surface of the rod 110a may face the second support plate 202 described herein. In other words, the upper surface of the rod 110a may be a side of the rod 110a disposed on the opposite side of the second support plate 202.

The locking means 1312a of the first auxiliary coupler 131a of the first driving member 100a may be disposed on the supporter 1311a of the first auxiliary coupler 131a. The size of the locking means 1312a in the second direction DR2 may be greater than the size of the supporter 1311a in the second direction DR2 such that both ends of the locking means 1312a are not supported by the supporter 1311a. That is, for example, the locking means 1312a may be formed such that both ends of the locking means 1312a are in indirect contact with the supporter 1311a (e.g., via a center portion of the locking means 1312a). Accordingly, a space may be formed between an end of the locking means 1312a and the upper surface of the rod 110a (e.g., in the third direction DR3), and a space may be formed between the opposite end of the locking means 1312a and the upper surface of the rod 110a (e.g., in the third direction DR3). The supporter 1311a and the locking means 1312a (also referred to herein as an engaging portion) may be formed as one body. The locking means 1312a of the first auxiliary coupler 131a of the first driving member 100a may be inserted into a guide hole GHa of the first auxiliary guide rail AGR1. In an example in which the first auxiliary coupler 131a is coupled to the guide hole GHa of the first auxiliary guide rail AGR1, both ends of the locking means 1312a may face the inner surfaces (or inner peripheral surfaces) of the first rail R11 and the second rail R12 of the first auxiliary guide rail AGR1, respectively.

The first auxiliary coupler 131a including the supporter 1311a and the locking means 1312a of the first driving member 100a may have, for example, a T-shape.

The second auxiliary coupler 132a of the first driving member 100a may include a supporter 1321a and a locking means 1322a, as illustrated in FIG. 12. The second auxiliary coupler 132a of the first driving member 100a may have substantially the same configuration as the first auxiliary coupler 131a of the first driving member 100a described herein, and the redundant descriptions will be omitted. The locking means 1322a of the second auxiliary coupler 132a of the first driving member 100a may be inserted into a guide hole GHb of the second auxiliary guide rail AGR2. In an example in which the second auxiliary coupler 132a is coupled to the guide hole GHb of the second auxiliary guide rail AGR2, both ends of the locking means 1322a of the second auxiliary coupler 132a may face the inner surfaces (or inner peripheral surfaces) of the first rail R11 and the second rail R12 of the second auxiliary guide rail AGR2, respectively.

As illustrated in FIG. 12, a third protrusion 333a may be disposed at the other end of the first driving member 100a. The third protrusion 333a may protrude from the other end of the first driving member 100a in the second direction DR2. The third protrusion 333a of the first driving member 100a may face the outer surface (or outer peripheral surface) of the second main guide rail MGR2.

FIG. 13 is a perspective view of the second driving member 100b of FIG. 9. FIG. 14 is an enlarged view of area A of FIG. 13. FIG. 15 is an enlarged view of area B of FIG. 13.

The second driving member 100b may include a rod 110b, a main coupler 120b, a first auxiliary coupler 131b, and a second auxiliary coupler 132b, as illustrated in FIG. 13.

The main coupler 120b of the second driving member 100b may be disposed at an end of the rod 110b (also referred to herein as the opposite an end of the rod 110b, as described herein). The main coupler 120b of the second driving member 100b may include a first protrusion 121b, a second protrusion 122b, and a connector 123b, as illustrated in FIG. 14.

The first protrusion 121b of the second driving member 100b may protrude from the rod 110b. For example, the first protrusion 121b may protrude in the second direction DR2.

The second protrusion 122b of the second driving member 100b may face the first protrusion 121b. The second protrusion 122b may protrude in the second direction DR2. The second protrusion 122b may be arranged parallel to the first protrusion 121b. The second main guide rail MGR2 may be disposed between the first protrusion 121b and the second protrusion 122b of the second driving member 100b. In other words, the second driving member 100b may be coupled to the second main guide rail MGR2 by the first protrusion 121b and the second protrusion 122b of the main coupler 120b. In an example in which the second driving member 100b is coupled to the second main guide rail MGR2, the first protrusion 121b of the second driving member 100b may face the outer surface (or outer peripheral surface) of the second main guide rail MGR2, and the second protrusion 122b of the second driving member 100b may face the inner surface (or inner peripheral surface) of the second main guide rail MGR2.

The connector 123b of the second driving member 100b may connect the first protrusion 121b with the second protrusion 122b. The connector 123b may protrude from the first protrusion 121b in the third direction DR3. The connector 123b may be disposed between the first protrusion 121b and the second protrusion 122b. One side of the connector 123b may be connected to the first protrusion 121b, and the opposite side of the connector 123b may be connected to the second protrusion 122b. The first protrusion 121b, the second protrusion 122b, and the connector 123b may be formed as one body.

The main coupler 120b including the first protrusion 121b, the second protrusion 122b, and the connector 123b may have, for example, a C-shape or a U-shape.

The first auxiliary coupler 131b of the second driving member 100b may include a supporter 1311b and a locking means 1312b, as illustrated in FIG. 14. The first auxiliary coupler 131b of the second driving member 100b is substantially identical to the first auxiliary coupler 131a of the first driving member 100a described herein, and the redundant descriptions will be omitted.

The second auxiliary coupler 132a of the second driving member 100b may include a supporter 1321b and a locking means 1322b, as illustrated in FIG. 15. The second auxiliary coupler 132b of the second driving member 100b is substantially identical to the second auxiliary coupler 132a of the first driving member 100a described herein, and the redundant descriptions will be omitted.

In some aspects, as illustrated in FIG. 15, a third protrusion 333b may be disposed on an end of the second driving member 100b. The third protrusion 333b may protrude from the end of the second driving member 100b in the second opposite direction. The third protrusion 333b of the second driving member 100b may face the outer surface (or outer peripheral surface) of the first main guide rail MGR1. The third protrusion 333b of the second driving member 100b may be substantially identical to the third protrusion 333a of the first driving member 100a described herein, and the redundant descriptions will be omitted.

It should be noted that embodiments of the present disclosure support changing the number and location of the auxiliary couplers 131a, 132a, 131b and 132b in various ways supportive of the display device 10.

FIG. 16 is a plan view of a plurality of driving members 100a and 100b and the second support plate 202 according to one or more embodiments of the present disclosure.

The display device 10 of FIG. 16 may include aspects of a display device 10 as described herein, and repeated descriptions of like elements are omitted for brevity. The display device 10 of FIG. 16 is different from the display device 10 of FIG. 9 in that auxiliary couplers and an auxiliary guide rail are disposed at different positions. The following description will focus on the difference between the display device 10 of FIG. 10 and the display device 10 of FIG. 9.

As illustrated in FIG. 16, for each of the first driving members 100a and second driving members 100b, the auxiliary coupler 130a of each first driving member 100a may be disposed at the center of the rod 110a of the first driving member 100a, and the auxiliary coupler 130b of each second driving member 100b may be disposed at the center of the rod 110b of the second driving member 100b.

The auxiliary coupler 130a of the first driving member 100a and the auxiliary coupler 130b of the second driving member 100b may be arranged in a row along the first direction DR1. In the example illustrated at FIG. 16, the auxiliary couplers 130a of the first driving members 100a and the auxiliary couplers 130b of the second driving members 100b may be arranged in a row along the first direction DR1.

Accordingly, for example, the auxiliary guide rail AGR may be located along the center of the plurality of driving members 100a and 100b.

Each of the auxiliary couplers 130a and 130b of FIG. 16 may have the same configuration as the first auxiliary coupler 131a of FIG. 9 described herein, and the auxiliary guide rail AGR of FIG. 16 may have the same configuration as the first auxiliary guide rail AGR1 of FIG. 9 described herein. The first rail R1 and the second rail R2 of the auxiliary guide rail AGR may be identical to the first rail R11 and the second rail R11 of the first auxiliary guide rail AGR1 illustrated in FIG. 9 described herein, respectively.

FIG. 17 is a plan view of a plurality of driving members 100a and 100b and a second support plate 202 according to an embodiment. FIG. 18 is a perspective view of the first driving member 100a of FIG. 17.

The display device 10 of FIG. 17 may include aspects of a display device 10 as described herein, and repeated descriptions of like elements are omitted for brevity. The display device 10 of FIG. 17 is different from the display device 10 of FIG. 16 in that the first driving member 100a and the second driving member 100b have different configurations. The following description will focus on the difference between the display device 10 of FIG. 17 and the display device 10 of FIG. 16.

As illustrated in FIGS. 17 and 18, the first driving member 100a may include a rod 110a and an auxiliary coupler 130a.

The rod 110a of the first driving member 100a may include a first protrusion 351a and a second protrusion 352a disposed on opposite sides in the second direction DR2.

The first protrusion 351a of the first driving member 100a may be disposed at an end of the rod 110a, and the second protrusion 352a of the first driving member 100a may be disposed at the other end of the rod 110a.

The first protrusion 351a of the first driving member 100a may be disposed on the outer surface of the first main guide rail MGR1, and the second protrusion 352a of the first driving member 100a may be disposed on the outer surface of the second main guide rail MGR2. In other words, the first protrusion 351a of the first driving member 100a may face the outer surface of the first main guide rail MGR1, and the second protrusion 352a of the first driving member 100a may face the outer surface of the second main guide rail MGR2.

The first protrusion 351a of the first driving member 100a may be identical to the third protrusion 333b of the second driving member 100b illustrated in FIG. 9 described herein.

The second protrusion 352a of the first driving member 100a may be identical to the third protrusion 333a of the first driving member 100a illustrated in FIG. 9 described herein.

It should be noted that the second driving member 100b of FIG. 17 may have the same configuration as the first driving member 100a of FIG. 17. In other words, the first driving member 100a and the second driving member 100b of FIG. 17 may be identical.

In some aspects, according to an embodiment, the second driving member 100b of FIG. 17 may have the same configuration as the second driving member 100b of FIGS. 9 and 16.

FIG. 19 is a plan view of a plurality of driving members 100a and 100b and the second support plate 202 according to an embodiment.

The display device 10 of FIG. 19 may include aspects of a display device 10 as described herein, and repeated descriptions of like elements are omitted for brevity. The display device 10 of FIG. 19 is different from the display device 10 of FIG. 17 in that the display device 10 of FIG. 19 includes a first auxiliary coupler 131a and a second auxiliary coupler 132a instead of the auxiliary coupler 130a described with reference to FIG. 17. The following description will focus on the difference between the display device 10 of FIG. 19 and the display device 10 of FIG. 17.

As illustrated in FIG. 19, the first driving member 100a may include a first auxiliary coupler 131a and a second auxiliary coupler 132a. That is, for example, each of the first driving members 100a may include a first auxiliary coupler 131a and a second auxiliary coupler 132a.

The first auxiliary coupler 131a and the second auxiliary coupler 132a of the first driving member 100a may be identical to the first auxiliary coupler 131a and the second auxiliary coupler 131a of the first driving member 100a as illustrated in FIG. 9 described herein, respectively.

It should be noted that the second driving member 100b of FIG. 19 may have the same configuration as the first driving member 100a of FIG. 19. In other words, the first driving member 100a and the second driving member 100b of FIG. 19 may be identical.

In some aspects, according to an embodiment, the second driving member 100b of FIG. 19 may have the same configuration as the second driving member 100b of FIGS. 9, 16 and 17.

FIG. 20 is a plan view of a plurality of driving members 100a and 100b and the second support plate 202 according to an embodiment. FIG. 21 is a perspective view of the first driving member 100a of FIG. 20. FIG. 22 is an enlarged view of area A of FIG. 21. FIG. 23 is an enlarged view of area B of FIG. 21.

As illustrated in FIGS. 20 and 21, the first driving member 100a may include a first sub-driving member 100aS1 and a second sub-driving member 100aS2 that are separated from each other.

The first sub-driving member 100aS1 may be coupled to the first main guide rail MGR1. For example, one side of the first sub-driving member 100aS1 may be coupled to the first main guide rail MGR1.

The first sub-driving member 100aS1 may include a first rod 110aS1 and a first main coupler 120aS1.

The first main coupler 120aS1 of the first sub-driving member 100aS1 may be disposed at an end of the first rod 110aS1. The first main coupler 120aS1 of the first sub-driving member 100aS1 may be coupled to the first main guide rail MGR1.

The first main coupler 120aS1 of the first sub-driving member 100aS1 may include a first protrusion 121aS1, a second protrusion 122aS1, and a connector 123aS1, as illustrated in FIGS. 21 and 22.

The first protrusion 121aS1 of the first sub-driving member 100aS1 may protrude from the first rod 110aS1. For example, the first protrusion 121aS1 may protrude in the second opposite direction.

The second protrusion 122aS1 of the first sub-driving member 100aS1 may face the first protrusion 121aS1. The second protrusion 122aS1 may protrude in the second opposite direction. The second protrusion 122aS1 may be arranged parallel to the first protrusion 121aS1. The first main guide rail MGR1 may be disposed between the first protrusion 121aS1 and the second protrusion 122aS1 of the first driving member 100aS1. In other words, the first sub-driving member 100aS1 may be coupled to the first main guide rail MGR1 by the first protrusion 121aS1 and the second protrusion 122aS1 of the main coupler 120aS1. In an example in which the first sub-driving member 100aS1 is coupled to the first main guide rail MGR1, the first protrusion 121aS1 of the first sub-driving member 100aS1 may face the outer surface (or outer peripheral surface) of the first main guide rail MGR1, and the second protrusion 122aS1 of the first sub-driving member 100a may face the inner surface (or inner peripheral surface) of the first main guide rail MGR1.

The connector 123aS1 of the first sub-driving member 100aS1 may connect the first protrusion 121aS1 with the second protrusion 122aS1. The connector 123aS1 may protrude from the first protrusion 121aS1 in the third direction DR3. The connector 123aS1 may be disposed between the first protrusion 121aS1 and the second protrusion 122aS1. One side of the connector 123aS1 may be connected to the first protrusion 121aS1, and the opposite side of the connector 123aS1 may be connected to the second protrusion 122aS1. The first protrusion 121aS1, the second protrusion 122aS2, and the connector 123aS1 may be formed as one body.

The first main coupler 120aS1 including the first protrusion 121aS1, the second protrusion 122aS1, and the connector 123aS1 may have, for example, a C-shape or a U-shape.

The second sub-driving member 100aS2 may be coupled to the second main guide rail MGR2. For example, one side of the second sub-driving member 100aS2 may be coupled to the second main guide rail MGR2.

The second sub-driving member 100aS2 may include a second rod 110aS2 and a second main coupler 120aS2.

The second main coupler 120aS2 of the second sub-driving member 100aS2 may be disposed at an end of the second rod 110aS2. The second main coupler 120aS2 of the second sub-driving member 100aS2 may be coupled to the second main guide rail MGR2.

The second main coupler 120aS2 of the second sub-driving member 100aS2 may include a first protrusion 121aS2, a second protrusion 122aS, and a connector 123aS2, as illustrated in FIGS. 21 and 23.

The first protrusion 121aS2 of the second sub-driving member 100aS2 may protrude from the second rod 110aS2. For example, the first protrusion 121aS2 may protrude in the second direction DR2.

The second protrusion 122aS2 of the second sub-driving member 100aS2 may face the first protrusion 121aS2. The second protrusion 122aS2 may protrude in the second direction DR2. The second protrusion 122aS2 may be parallel to the first protrusion 121aS2. The second main guide rail MGR2 may be disposed between the first protrusion 121aS2 and the second protrusion 122aS2 of the second driving member 100aS2. In other words, the second sub-driving member 100aS2 may be coupled to the second main guide rail MGR2 by the first protrusion 121aS2 and the second protrusion 122aS2 of the second main coupler 120aS2. In an example in which the second sub-driving member 100aS2 is coupled to the second main guide rail MGR2, the first protrusion 121aS2 of the second sub-driving member 100aS2 may face the outer surface (or outer peripheral surface) of the second main guide rail MGR2, and the second protrusion 122aS2 of the second sub-driving member 100aS2 may face the inner surface (or inner peripheral surface) of the second main guide rail MGR2.

The connector 123aS2 of the second sub-driving member 100aS2 may connect the first protrusion 121aS2 with the second protrusion 122aS2. The connector 123aS2 may protrude from the first protrusion 121aS2 in the third direction DR3. The connector 123aS2 may be disposed between the first protrusion 121aS2 and the second protrusion 122aS2. One side of the connector 123aS2 may be connected to the first protrusion 121aS2, and the opposite side of the connector 123aS2 may be connected to the second protrusion 122aS2. The first protrusion 121aS2, the second protrusion 122aS2, and the connector 123aS2 may be formed as one body.

The second main coupler 120aS2 including the first protrusion 121aS2, the second protrusion 122aS2, and the connector 123aS2 may have, for example, a C-shape or a U-shape.

The opposite end of the first sub-driving member 100aS1 of the first driving member 100a and the opposite end of the second sub-driving member 100aS2 of the first driving member 100a may face each other. For example, the opposite end of the first sub-driving member 100aS1 and the opposite end of the second sub-driving member 100aS2 may face each other in the second direction DR2.

It should be noted that the second driving member 100b of FIG. 20 may have the same configuration as the first driving member 100a of FIG. 19. For example, the second driving member 100b may include a first sub-driving member 100bS1 and a second sub-driving member 100bS2 that are separated from each other. The first sub-driving member 100bS1 of the second driving member 100b may be coupled to the first main guide rail MGR1, and the second sub-driving member 100bS2 of the second driving member 100b may be coupled to the second main guide rail MGR2.

In some aspects, according to an embodiment, the second driving member 100b of FIG. 20 may have the same configuration or substantially the same configuration as the second driving member 100b of FIGS. 9, 16 and 17.

FIG. 24 is a plan view of a plurality of driving members 100a and 100b and the second support plate 202 according to an embodiment.

The display device 10 of FIG. 24 may include aspects of a display device 10 described herein, and repeated descriptions of like elements are omitted for brevity. The display device 10 of FIG. 24 is different from the display device 10 of FIG. 20 in that the display device 10 of FIG. 24 further includes a first auxiliary coupler 131aS1 and a second auxiliary coupler 132aS1. The following description will focus on the difference between the display device 10 of FIG. 24 and the display device 10 of FIG. 20.

As illustrated in FIG. 24, a first sub-driving member 100aS1 of a first driving member 100a may further include a first auxiliary coupler 131aS1, and the second sub-driving member 100aS2 of the first driving member 100a may further include a second auxiliary coupler 132aS2. That is, for example, each of the first sub-driving members 100aS1 may include a first auxiliary coupler 131aS1, and each of the second sub-driving members 100aS2 may include a second auxiliary coupler 132aS2.

The first auxiliary coupler 131aS1 and the second auxiliary coupler 132aS2 of FIG. 24 may be identical to the first auxiliary coupler 131a and the second auxiliary coupler 132a of FIG. 19 described herein, respectively.

It should be noted that the second driving member 100b of FIG. 24 may have the same configuration as the first driving member 100a of FIG. 24. For example, the first sub-driving member 100bS1 of the second driving member 100b may further include the first auxiliary coupler 131bS1, and the second sub-driving member 100bS2 of the second driving member 100b may further include the second auxiliary coupler 132bS2. That is, for example, each of the first sub-driving members 100bS1 may include a first auxiliary coupler 131bS1, and each of the second sub-driving members 100bS2 may include a second auxiliary coupler 132bS2.

In some aspects, according to an embodiment, the second driving member 100b of FIG. 24 may have the same configuration as the second driving member 100b of FIGS. 9, 16, 17 and 20.

FIG. 25 is a view for illustrating the expanded shape of the display panel PNL of FIG. 5.

As illustrated in FIG. 25, when the display device 10 slides open or is slid open (e.g., partially or fully open), i.e., the display device 10 is in the second state, the display area may further include an expanded second display area DA_2 in addition to the first display area DA_1.

In some embodiments, as illustrated in FIG. 25, the first driving members 100a move counterclockwise along a first main guide rail MGR1, a first auxiliary guide rail AGR1, and a second auxiliary guide rail AGR2. In some aspects, although not illustrated in the drawings, the second driving members 100b may move counterclockwise along a second main guide rail MGR2, a first auxiliary guide rail AGR1, and a second auxiliary guide rail AGR2.

In other words, as the first driving members 100a and the second driving members 100b move counterclockwise along the first main guide rail MGR1 (or the second main guide rail MGR2), the first auxiliary guide rail AGR1, and the second auxiliary guide rail AGR2, the display area of the display panel PNL may expand.

In the display device according to the embodiments described herein, since one driving member is selectively coupled to one of (e.g., only one) of the two main guide rails MGR1 and MGR2, the selective coupling supports the prevention of distortion of the driving member when the driving member moves. That is, for example, the selective coupling of each driving member (e.g., a first driving member 100a, a second driving member 100b) to one of the two main guide rails MGR1 and MGR2 supports the prevention of distortion of the driving member when the driving member moves. For example, embodiments of the present disclosure as described herein may prevent distortion such as, for example, bending of the driving member, misalignment of the driving member, imbalance of the driving member, and the like.

For example, in some other display devices, when a main coupler is installed at each of the both ends of the rod of the driving member, if the main coupler at an end (hereinafter referred to as a first main coupler) and the main coupler at the other end (hereinafter referred to as a second main coupler) are not properly aligned, the driving timing of the first main coupler coupled to the first main guide rail may not coincide with the driving timing of the second main coupler coupled to the second main guide rail. When this happens, the driving member including the first main coupler and the second main coupler may be distorted. In contrast, according to the example embodiments of the present disclosure, one driving member is connected to one main guide rail through one coupler in the display device (e.g., each first driving member 100a is coupled to the first main guide rail MGR1 through a respective main coupler 120a, each second driving member 100b is coupled to the second main guide rail MGR2 through a respective main coupler 120b), and no alignment issue occurs between the main couplers. As a result, the prevention of the alignment issue may prevent distortion of the driving members (e.g., first driving members 100a, second driving members 100b) and the display panel 10 disposed on the driving members.

In some aspects, in a display device 10 according to the example embodiments described herein, the main coupler 120a of the first driving member 100a and the main coupler 120b of the second driving member 100b are alternately coupled to different main guide rails MGR1 and MGR2, which may ensure the driving balance of the plurality of driving members 100a and 100b even though one driving member is coupled to one main guide rail. That is, for example, the main couplers 120a of the first driving members 100a and the main couplers 120b of the second driving members 100b are alternately coupled to the first main guide rail MGR1 and the second main guide MGR2.

In some aspects, since each driving member includes one main coupler (e.g., each first driving member 100a includes a main coupler 120a, each second driving member 100b includes a main coupler 120b), the number of main couplers can be reduced, thereby reducing fabrication costs and the weight of each driving member accordingly. In some aspects, since the total number of main couplers can be reduced, the friction between each driving member and the main couplers (also referred to herein as main guide couplers) can be reduced, and the reduced friction supports easier movement of each driving member with less force. The reduced quantity of main couplers supports a reduction in fabrication costs and the weight of a display device 10 described herein.

In some aspects, the display device according to the embodiments described herein, the driving force for driving the driving members can be distributed by the auxiliary couplers and the auxiliary guide rails, and the distribution of the driving force supports increases to the lifespan of the display device 10. In some aspects, since the driving members can be supported by the auxiliary couplers and the auxiliary guide rails, distortion of the driving members can be prevented.

In some aspects, in a display device 10 according to the example embodiments described herein, one or more driving members may include a plurality of sub-driving members separated from each other, and thus the load on the first main guide rail and the second main guide rail can be reduced, and also the distortion of the driving members can be prevented.

Aspects of the present disclosure support combining any suitable features of the example embodiments described herein. For example, in some embodiments, a display device 10 may include a configuration based on any suitable combination of elements described at least with reference to FIG. 9, FIG. 16, FIG. 17, FIG. 19, FIG. 20, and/or FIG. 24 and other related descriptions and figures. In an example, (not illustrated) a display device 10 may include first driving members 100a and second driving members 100b as described herein. In the example, (not illustrated), one or more first driving members 100a may be implemented as described at least with reference to FIGS. 9 through 19, and one or more other first driving members 100a may be implemented as described at least with reference to FIGS. 20 through 24 (e.g., including a first sub-driving member 100aS1 and a second sub-driving member 100aS2). Additionally, or alternatively, (not illustrated), one or more second driving members 100b may be implemented as described at least with reference to FIGS. 9 through 19, and one or more other second driving members 100b may be implemented as described at least with reference to FIGS. 20 through 24 (e.g., including a first sub-driving member 100bS1 and a second sub-driving member 100bS2).

It will be able to be understood by one of ordinary skill in the art to which the present disclosure belongs that the present disclosure may be implemented in other specific forms without changing the technical spirit or essential features of the present disclosure. Therefore, it is to be understood that the example embodiments described herein are illustrative rather than being restrictive in all aspects. It is to be understood that the scope of the present disclosure are defined by the claims rather than the detailed description described herein and all modifications and alterations derived from the claims and their equivalents fall within the scope of the present disclosure.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments only and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

The term “substantially,” as used herein, means approximately or actually equal (e.g., within a threshold percent of equal). The term “substantially simultaneously,” as used herein, means approximately or actually at the same time (e.g., within a threshold percent of equal). The term “substantially the same,” as used herein, means approximately or actually the same (e.g., within a threshold difference amount).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

What is claimed is:

1. A display device comprising:
a display panel;
a first main guide rail and a second main guide rail disposed on a first side and a second side of the display panel, respectively; and
a first driving member disposed between the first main guide rail and the second main guide rail,
wherein the first driving member is selectively coupled to the first main guide rail from among the first main guide rail and the second main guide rail and is not coupled to the second main guide rail.

2. The display device of claim 1, wherein the first driving member comprises:
a rod; and
a main coupler disposed at an end of the rod and coupled to the first main guide rail.

3. The display device of claim 2, wherein the main coupler of the first driving member comprises:
a first protrusion protruding from the rod and facing an outer surface of the first main guide rail; and
a second protrusion disposed on an opposite side of the first protrusion and facing an inner surface of the first main guide rail.

4. The display device of claim 3, wherein the main coupler of the first driving member further comprises a connector connecting the first protrusion with the second protrusion.

5. The display device of claim 2, wherein the first driving member further comprises a third protrusion protruding from an opposite end of the rod.

6. The display device of claim 5, wherein the third protrusion faces an outer surface of the second main guide rail.

7. The display device of claim 2, wherein the first driving member further comprises an auxiliary coupler disposed on the rod.

8. The display device of claim 7, further comprising an auxiliary guide rail to which the auxiliary coupler is coupled.

9. The display device of claim 8, wherein the auxiliary guide rail comprises a first rail and a second rail that are spaced apart from and face each other, and define a guide hole into which the auxiliary coupler is coupled.

10. The display device of claim 9, wherein the auxiliary coupler comprises: a supporter protruding from an upper surface of the rod; and a locking means disposed on the supporter and inserted into the guide hole.

11. The display device of claim 7, wherein the auxiliary coupler is disposed at a center of the rod.

12. The display device of claim 7, wherein the auxiliary coupler comprises:
a first auxiliary coupler disposed adjacent to an end of the rod; and
a second auxiliary coupler disposed adjacent to an opposite end of the rod.

13. The display device of claim 12, further comprising:
a first auxiliary guide rail to which the first auxiliary coupler is coupled; and
a second auxiliary guide rail to which the second auxiliary coupler is coupled.

14. The display device of claim 13, wherein the first auxiliary guide rail and the second auxiliary guide rail are disposed between the first main guide rail and the second main guide rail.

15. The display device of claim 14, wherein the first auxiliary guide rail is disposed adjacent to the first main guide rail, and the second auxiliary guide rail is disposed adjacent to the second main guide rail.

16. The display device of claim 1, further comprising:
a second driving member disposed adjacent to the first driving member between the first main guide rail and the second main guide rail,
wherein the second driving member is selectively coupled to the second main guide rail from among the first main guide rail and the second main guide rail and is not coupled to the first main guide rail.

17. The display device of claim 16, wherein the second driving member comprises:
a rod; and
a main coupler disposed at an end of the rod and coupled to the second main guide rail.

18. The display device of claim 17, wherein the main coupler of the second driving member comprises:
a first protrusion protruding from the rod and facing an outer surface of the second main guide rail; and
a second protrusion disposed on an opposite side of the first protrusion and facing an inner surface of the second main guide rail.

19. The display device of claim 18, wherein the main coupler of the first driving member further comprises a connector connecting the first protrusion with the second protrusion.

20. A display device comprising:
a display panel;
a first main guide rail and a second main guide rail disposed on a first side and a second side of the display panel, respectively;
an auxiliary guide rail disposed between the first main guide rail and the second main guide rail; and
a driving member disposed between the first main guide rail and the second main guide rail and coupled to the auxiliary guide rail.

21. The display device of claim 20, wherein an end of the driving member faces an outer surface of the first main guide rail, and an opposite end of the driving member faces an outer surface of the second main guide rail.

22. The display device of claim 20, wherein the driving member comprises an auxiliary coupler coupled to the auxiliary guide rail.

23. A display device comprising:
a display panel;
a first main guide rail and a second main guide rail disposed on a first side and a second side of the display panel, respectively; and
a driving member disposed between the first main guide rail and the second main guide rail,
wherein the driving member comprises a first sub-driving member and a second sub-driving member that are separated from each other and coupled to the first main guide rail and the second main guide rail, respectively.

24. The display device of claim 23, wherein the first sub-driving member comprises a first main coupler coupled to the first main guide rail, and the second sub-driving member comprises a second main coupler coupled to the second main guide rail.

25. The display device of claim 23, wherein the first sub-driving member comprises a first auxiliary coupler, and the second sub-driving member comprises a second auxiliary coupler.

26. The display device of claim 25, further comprising:
a first auxiliary guide rail to which the first auxiliary coupler is coupled; and
a second auxiliary guide rail to which the second auxiliary coupler is coupled.
